(19) United States
(12) Patent Application Publication
(10) Pub. No.: US 2007/0171076 A1
(43) Pub. Date: Jul. 26, 2007

(54) LOW-FREQUENCY RADIO TAG ENCAPSULATING SYSTEM

(75) Inventors: John K. Stevens, Stratham, NH (US); Paul Waterhouse, Selkirk (CA)

Correspondence Address: Oppedahl Patent Law Firm LLC - VAI, P.O. BOX 4850, FRISCO, CO, 80443-4850, US

(73) Assignee: Visible Assets, Inc., Mississauga (CA)

(21) Appl. No.: 11/467,864

(22) Filed: Aug. 28, 2006

Related U.S. Application Data
(60) Provisional application No. 60/712,730, filed on Aug. 29, 2005.
(60) Provisional application No. 60/820,209, filed on Jul. 24, 2006.

(51) Int. Cl. G08B 13/14; H01L 23/02; H01L 23/28

(52) U.S. Cl. 340/572.8; 257/679; 257/787

(57) ABSTRACT

A sturdy radio tag has an antenna and semiconductor chip tuned to low frequency, encapsulated using a low-temperature, low-pressure, low-viscosity injection molding process.

This application claims priority from U.S. application No. 60/712,730 filed Aug. 29, 2006 and entitled “Low frequency radio tag and encapsulating system,” and from U.S. application No. 60/820,209 filed Jul. 24, 2006 and entitled “Tag challenge,” which applications are incorporated herein by reference for all purposes.

### FIELD OF THE INVENTION

The present invention relates to a low-frequency radio transceiver tag encapsulated using a low-viscosity and low-temperature encapsulation method. This produces a sealed, low-cost long-range visibility system for use in a variety of different industries.

### BACKGROUND OF THE INVENTION

Radio Frequency Identity tags or RFID tags have a long history and have been based largely upon the use of “transponders” tags that make use of a backscattered signal with a fixed pre-programmed ID. These tags are often designed to replace bar codes and are capable of low-power two-way communications. The first clear description of a transponder device can be found in U.S. Pat. No. 3,406,391 issued in 1968 and was designed to track moving vehicles. Many other similar devices were described in the following years (e.g. U.S. Pat. No. 03,713,148 in 1973, The Mercury News, RFID pioneers discuss its origins, Sun, Jul. 18, 2004, and U.S. Pat. No. 859,624 in 1975). In contrast an active RFID tag has a battery to power the tag circuitry. Active tags and devices operating in the 13.56 MHz to 2.3 GHz frequency range. and also work as transponders (U.S. Pat. No. 6,700,491). A transponder uses a carrier transmitted by a base station to and backscattered from the tag. The tag usually communicates by simply shorting or detuning a resonant-tuned antenna to produce a change in the reflected energy. This backscattered signal approach minimizes the power required to transmit a return signal. If RFID tags working at higher frequencies used a transceiver method that provided active energy into the antenna as alternative to backscattered mode, the energy required to transmit any distance would be prohibitive (US2004/0217865 A1). A reflected signal-detection method also minimizes the complexity of the tag circuitry. Passive RFID transponder tags do not have a battery and use the same carrier signal for power.

Active transceiver tags in the high-frequency range (433 Mhz) do exist (e.g. SaviTag ST-654), but are expensive (over $100.00 US) and large (videotape size, 6.25×2.125×1.125 inches) because of the power issues. These tags also must use replaceable batteries since even with such a 1.5 inch by 6 inch Li battery the tags are only capable of 2,500 reads and writes.

Passive transponder RFID tags have an antenna consisting of a wire coil or an antenna coil etched onto a PC board. These antenna coils in passive tags serve four functions:
1. It serves as an antenna for detecting the carrier radio signals that contains the data signal;
2. It serves as a power source. The tag receives a carrier signal from a base station and uses the carrier signal to provide power to the integrated circuitry and logic on the tag; and
3. It may also serve as a frequency and phase reference for radio communications. The tag can use the same coil to receive a carrier at a precise frequency and phase reference for the circuitry within the radio tag for communications back to the reader/writer.
4. It can also serve as a clock used to drive the logic and circuitry within the integrated circuit. In some cases the carrier signal is modulated to produce a lower clock speed.

It is generally assumed that a passive transponder tag is less costly than an active transponder tag since it has fewer components and is less complex. Thus, a passive transponder tag has the potential to eliminate the need and cost for a battery as well as an internal frequency reference standard such as a crystal or temperature compensated oscillator (e.g U.S. Pat. No. 05,241,286) for precise control of phase and frequency. An active transponder tag eliminates the crystal and requires the extra cost of a battery but also provides for enhanced amplification of signals on the transponder. In addition, since passive transponder tags have precise known phase and frequency since they can use an external common reference (the carrier signal), it is possible to enhance extraction of the tag signal from background noise (U.S. Pat. No. 04,821,291). It is also possible to use this precise reference to provide enhanced anti-collision methods so as to make it possible to read many tags within a carrier field (US 6,297,734, US 6,566,997, US 5,995,019, US 5,591,951). Transponder RFID tags typically operate at several different frequencies within the Part-15 rules of the FCC (Federal Communication Commission) between 10 kHz to 500 kHz (Low frequency or Ultra Low Frequency ULF), 13.56 MHz (High Frequency, HF) in or 433 MHz and 868/915 MHz or 2.2 GHz (Ultra High Frequency UHF). The higher frequencies are typically used to provide high bandwidth for communications, on a high-speed conveyor for example, or where many thousands of tags must be read rapidly. In addition, the higher frequencies are more efficient for transmission of signals and require much smaller antennas for optimal transmission. (It may be noted that a self-resonated antenna for 915 MHz can have a diameter as small as 0.5 cm).

In previous disclosures we have shown that the prior art has assumed that low-frequency tags are slow, short-range, and too costly because of the antenna. However we have disclosed the many unexpected advantages of a low-frequency active tag that works as a transceiver for tracking objects as opposed to a transponder, similar to the Savi ST-654. These tags have a full two-way digital communications protocol, digital static memory and optional processing ability, with memory and ranges of up to 100 feet. The tags are far less costly than other active transceiver tags (many in the dollar range). Such tags are often less costly than passive RFID tags that make use of EEPROM. These low-frequency transceiver tags also provide a high level of security since they have an on-board crystal than can provide a date-time stamp making full AES encryption and one-time time-based pads possible. In most cases these tags have a battery life of over 15 years using inexpensive quarter-sized Li batteries with 10,000 to 25,000 transmissions.

The low-frequency tags may use amplitude modulation or in some case phase modulation, and can have ranges of many tens of feet, and (with use of a loop antenna) up to a hundred feet. The tags include a battery, a chip and a crystal. In many cases the total cost for such a tag can be less than HF and ULF passive transponder tags, especially if the transponder includes EEPROM, has longer range. In cases where the transponder tags use EEPROM the low frequency active transceiver tag can actually be faster since it use sRam for storage. Finally, because these new active transceiver tags use induction as the primary communication mode, and induction works work optimally at low frequencies LF they are largely immune to nulls often found near steel and liquids with HF and UHF tags. US 2004-0217865 summarizes much of the prior art and supports the non-obvious nature of a low frequency transceiver as a RF-ID tag.

Wireless Smart Cards often called IC Cards are usually simply passive transponder tags (U.S. Pat. No. 176,433 B1) embedded in injection molded plastics. The art of encapsulating electronics is well known and was developed to produce packaged integrated circuits (U.S. Pat. No. 4,857,483) However, producing thin cards that meet the international thickness standard of 0.78 mm has created many special new problems. Suspending the electronic devices within the thin card has been a challenge (US 5,955,021, US 6,025,054), and maintaining a commercial-grade card surface. An additional serious problem has been that the lowest cost production method for these cards can only be achieved with high-pressure injection molding, similar to that used to encapsulate integrated circuits and other active components (US 4,043,027, US 3,367,025, US 4,857,483).

One major problem for many other electronic components such as batteries, capacitors, Liquid Crystal Displays (LCDs), and Light Emitting Diodes (LEDs) and crystals, is the fact that high-pressure injection molding may lead to elevated temperatures of over 200 C. for several minutes. This can evaporate the electrolyte of a battery, and can either decrease the battery life or in some cases lead to a faulty battery. It will destroy most LCDs, and many LEDs. In some cases batteries and other components have been specifically designed to overcome these high-temperature effects (U.S. Pat. No. 5,089,877) but the cost of the high-temperature-resistant components may be several times greater than an equivalent low-temperature item. This becomes more complex when a molded encapsulated product or device is created since the batteries cannot be replaced. In some cases this problem has been solved by adding rechargeable batteries, however the elevated temperatures and complex chemistry make this an unattractive solution.

### SUMMARY OF THE INVENTION

A sturdy radio tag has an antenna and semiconductor chip tuned to low frequency, encapsulated using a low-temperature and low-viscosity injection molding process.

### DESCRIPTION OF THE DRAWING

FIG. 1 shows an active low frequency transceiver tag.

FIG. 2 shows placement of the components inside the encapsulated parts.

FIG. 3 shows a typical ID card.

FIG. 4 shows an encapsulated livestock tag.

FIG. 5 shows an encapsulated livestock tag for hogs and smaller cattle.

FIG. 6 shows an encapsulated 2 mm tag.

FIG. 7 shows an inside cutaway of the tag of FIG. 6.

FIG. 8 shows a wristband.

FIG. 9 shows an evidence tracking tag.

FIG. 10 shows a loop antenna.

FIG. 11 shows a tag attached to luggage.

FIG. 12 shows a similar tag to that seen in FIG. 11 with a printed overlay.

FIG. 13 shows a tag attached to a 2-ml vial.

FIG. 14 shows a standard RFID chip and a sturdy tag according to the invention.

FIG. 15 shows a sturdy tag according to the invention, placed on a marble slab and struck with a sledge hammer.

FIG. 16 shows a sturdy tag according to the invention, nearby to a block of wood with a small hole in it, to be used for driving three nails.

FIG. 17 shows the block of wood of FIG. 16, positioned over a nail, with the sturdy tag upon the block of wood, ready to be struck by a hammer.

FIG. 18 shows all three nails of FIG. 16, being driven.

FIG. 19 shows the three nails of FIG. 18, driven fully in.

FIG. 20 shows tag reads with correct CRCs during the hammering activity of FIG. 18.

FIG. 21 shows a bet being paid because the tag reads were successful even after the hammering activity of FIG. 18.

FIG. 22 shows a tongue of a forklift positioned over a sturdy tag, in preparation for a test of the tag.

FIG. 23 shows the forklift pushing down upon the tag with enough force to lift both front wheels of the forklift.

FIG. 24 shows tag reads with correct CRCs during the pressing activity of FIG. 23.

FIG. 25 shows a bet being paid because the tag reads were successful even after the pressing activity of FIG. 23.

### DETAILED DESCRIPTION OF THE INVENTION

U.S. Pat. No. 6,256,873, incorporated herein by reference for all purposes, teaches the use of a low-pressure modified Reaction Injection Molding (RIM) method for fabrication of smart cards. One of the major advantages of the method is that temperatures can be maintained at levels below 100 F. so that temperature sensitive and much lower cost components may be used in these cards. However, this creates a new problem that if a battery is used in the tag with RIM encapsulation, the battery cannot be replaced. The batteries therefore may be rechargeable, making them expensive and often creating disposal problems dues to toxic materials required for recharging. Alternatively, the embedded device must use battery-assisted backscattered mode similar to that described in US 2004-0217865, and U.S. Pat. No. 6,700,491 to minimize power consumption.

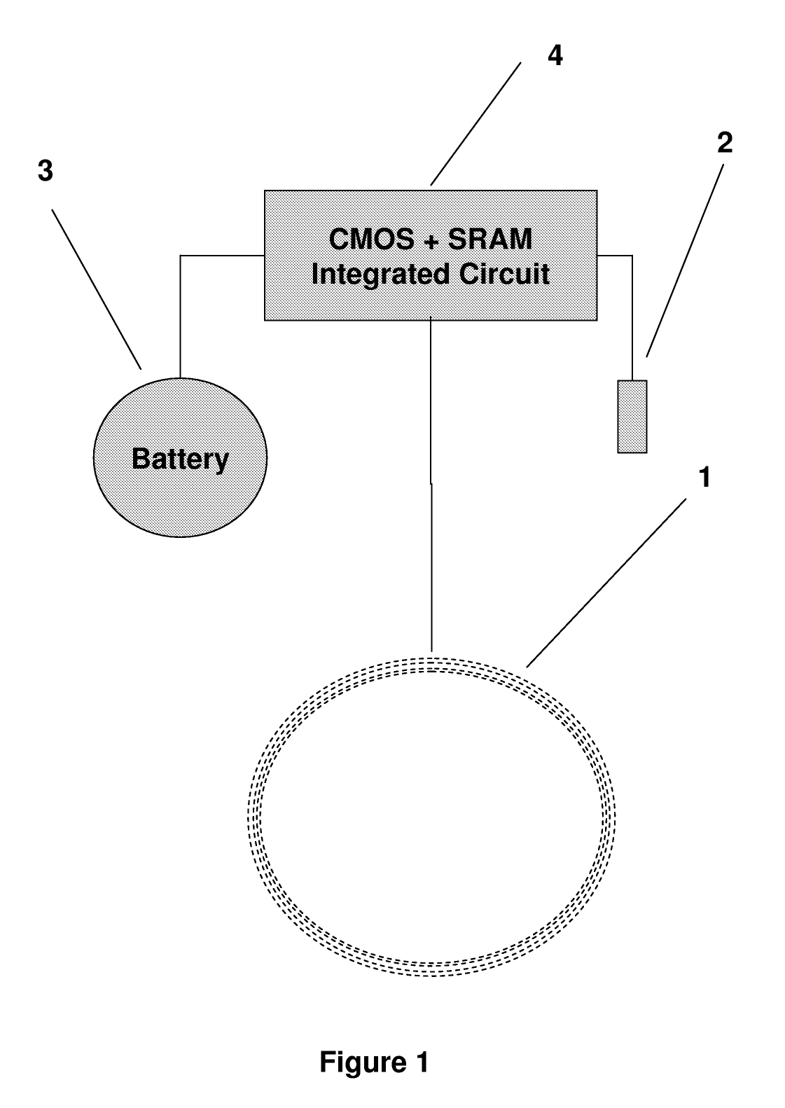

Turning to FIG. 1, the active low-frequency transceiver tag consists of four basic components:
1. the antenna, typically a wound loop or coil, that has been tuned to low frequency (138 kHz),
2. a 32-kHz watch crystal used as a frequency reference to run the clock and keep date and time used to maintain security keys,
3. metal gate CMOS chips or silicon gate CMOS chip with optional sRam, and
4. a thin Li battery.

Other optional components may be used including tuning capacitors and capacitors to maximize the gain on amplifiers contained in the chip.

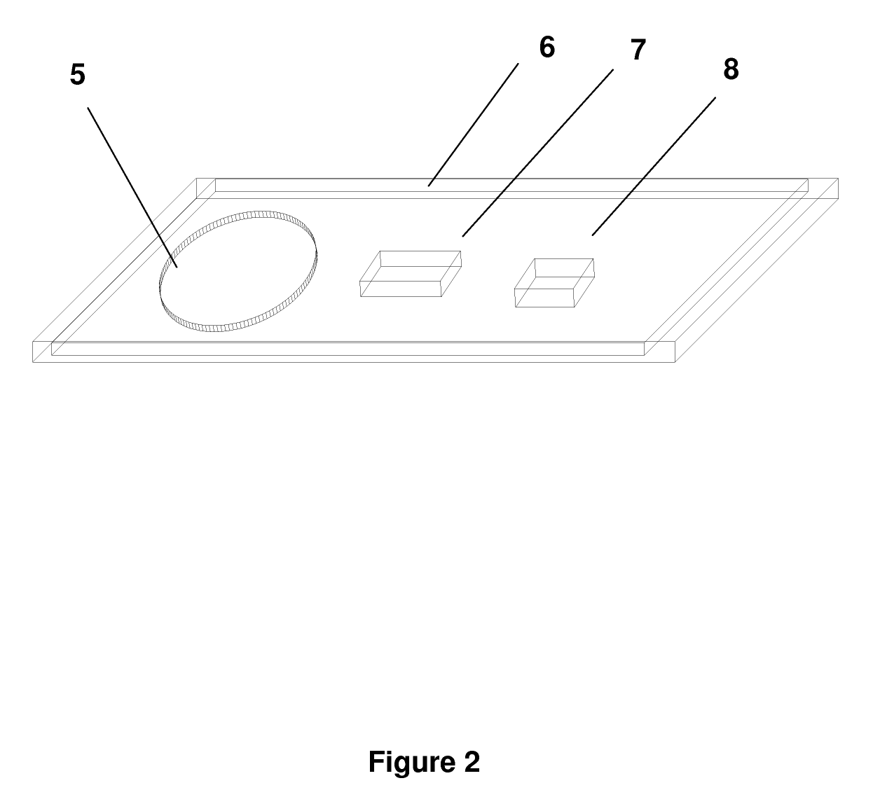

FIG. 2 shows the placement of the components inside the encapsulated parts. The Li battery 5 can be obtained in under 0.5 mm thickness for credit card form factor applications, however in most cases a CR2512 or CR1612 can be used creating a 2-mm card, 6 is the wire loop antenna placed near the outside edge to maximize the area, 7 the chip and 8 a crystal.

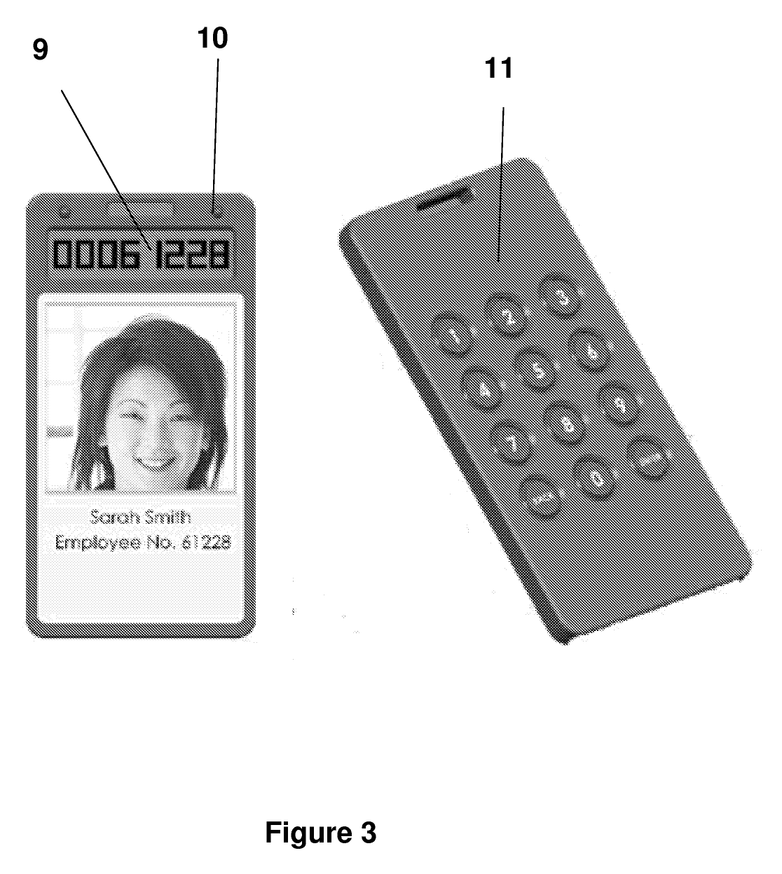

FIG. 3 shows a typical ID card that might include an LCD display 9, LEDs 10, with an optional keypad 11 on the back to enter PIN numbers for access control.

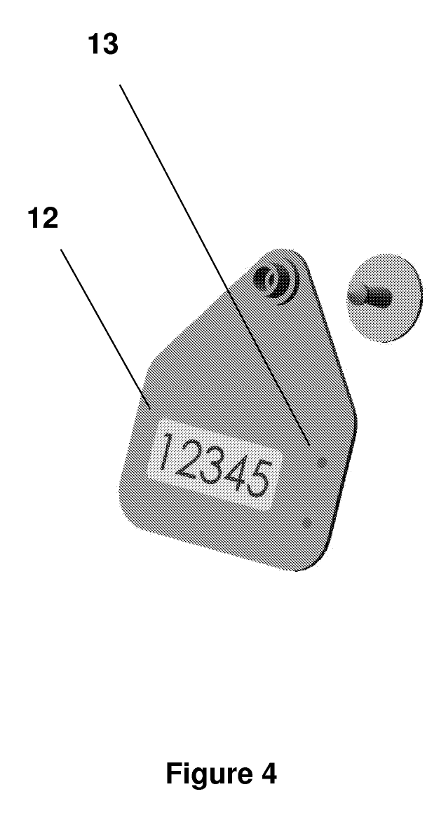

FIG. 4 shows an encapsulated livestock tag with display 12, and optional LED 13. The tag would be placed on the inside of an ear.

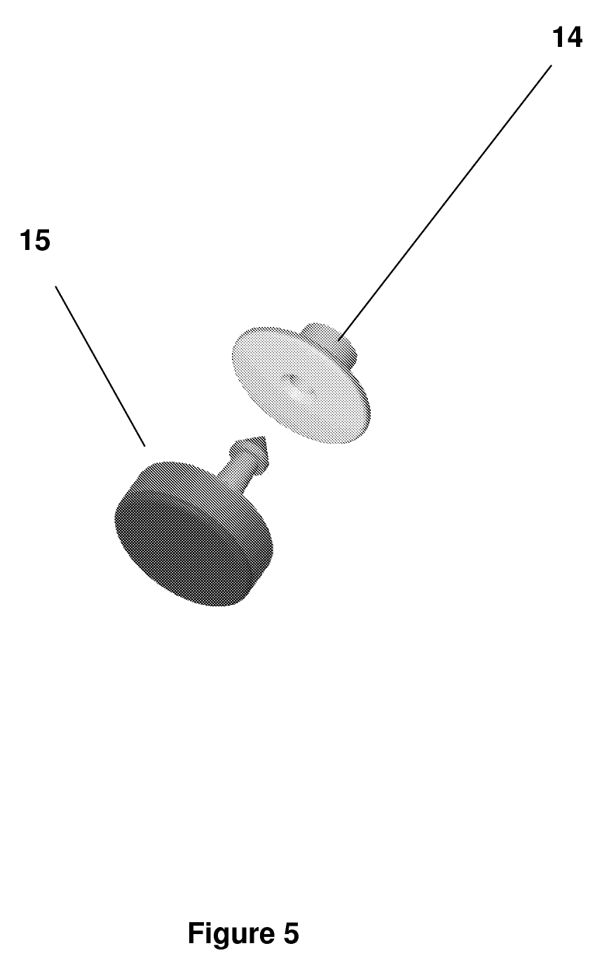

FIG. 5 shows an encapsulated livestock tag for hogs and smaller cattle. The electronics are sealed in an encapsulated package 15 with a capture piece 14 that may be injection molded.

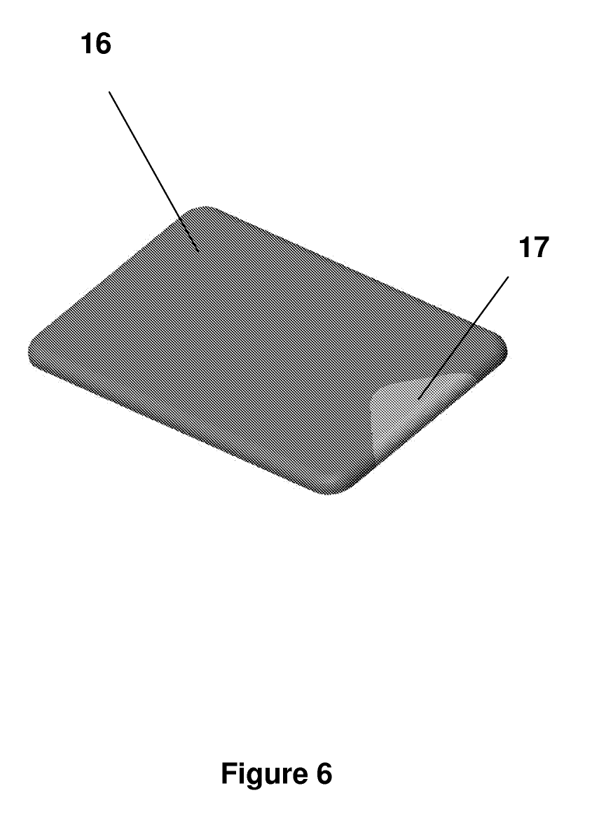

FIG. 6 shows an encapsulated 2-mm tag 16, with embedded LEDs 17.

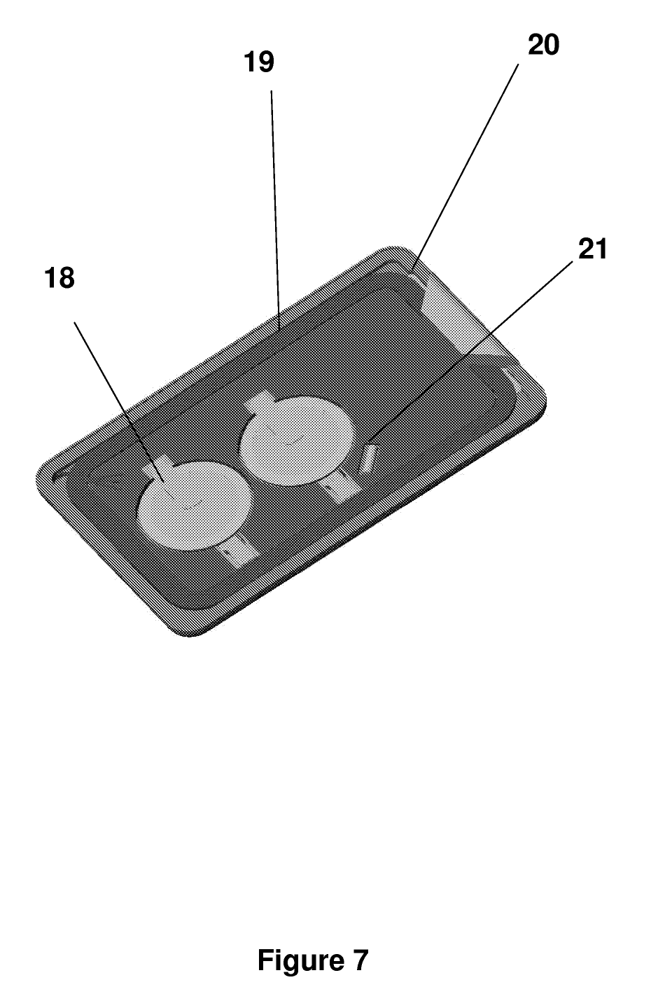

FIG. 7 is an inside cutaway view of the tag of FIG. 6, with batteries 18, antenna 19, LEDs 20, and crystal 21. The chip is on the underside of the PC board.

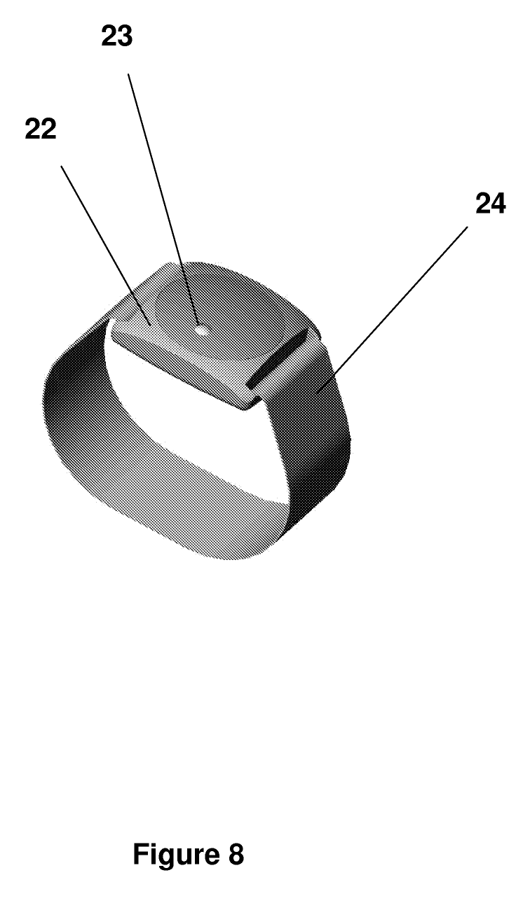

FIG. 8 shows a wristband 22 with an optional LED 23, and a conventional wristband attachment 24. Using this system, the electronic encapsulated portion may be fitted over existing hospital ID bands.

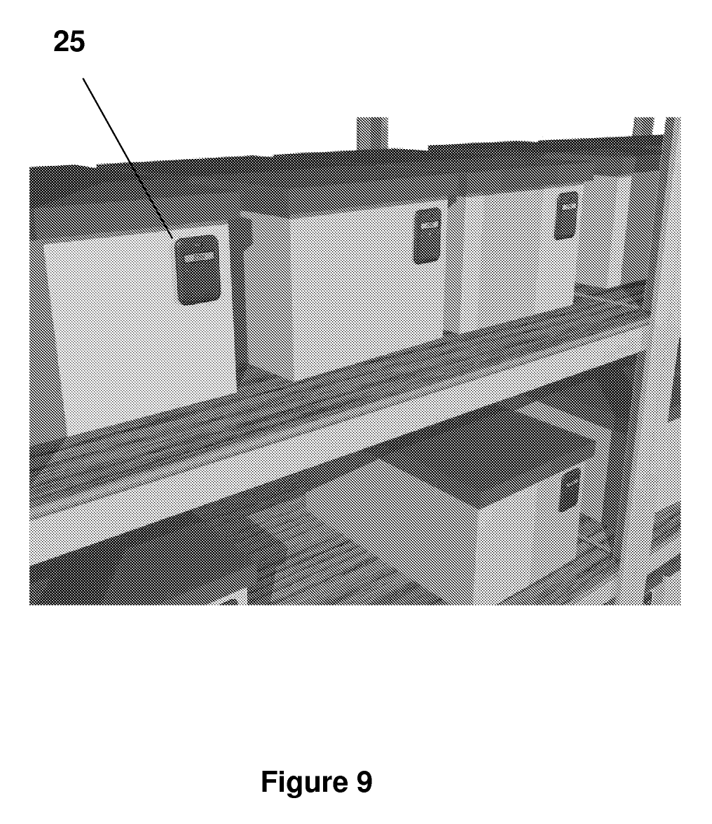

FIG. 9 shows an evidence tracking tag 25 on an evidence box.

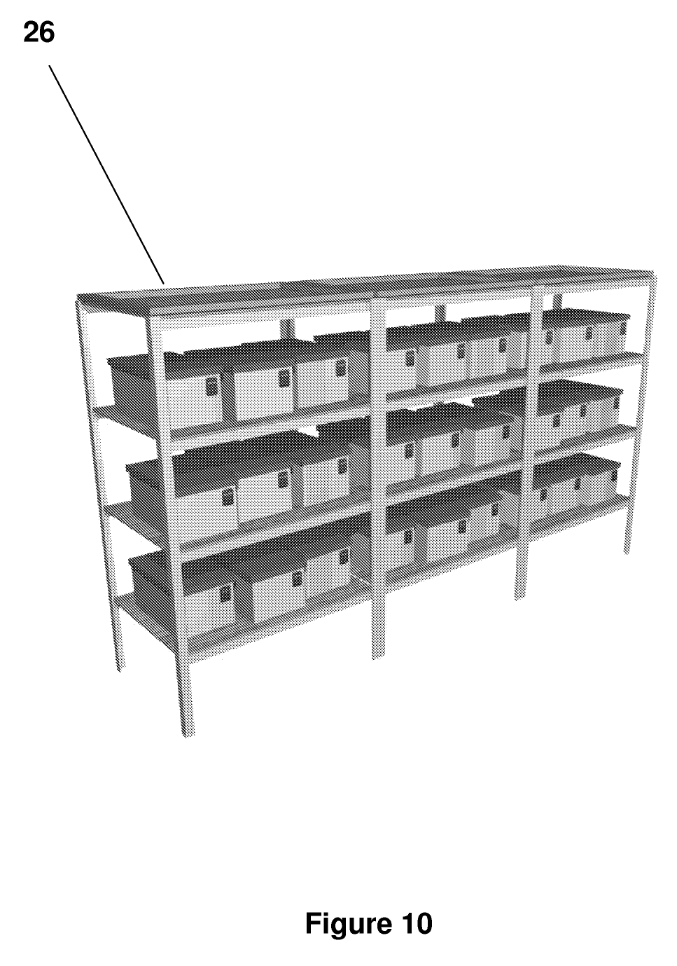

FIG. 10 shows a loop 26 antenna on a shelf to read the tags shown in FIG. 9.

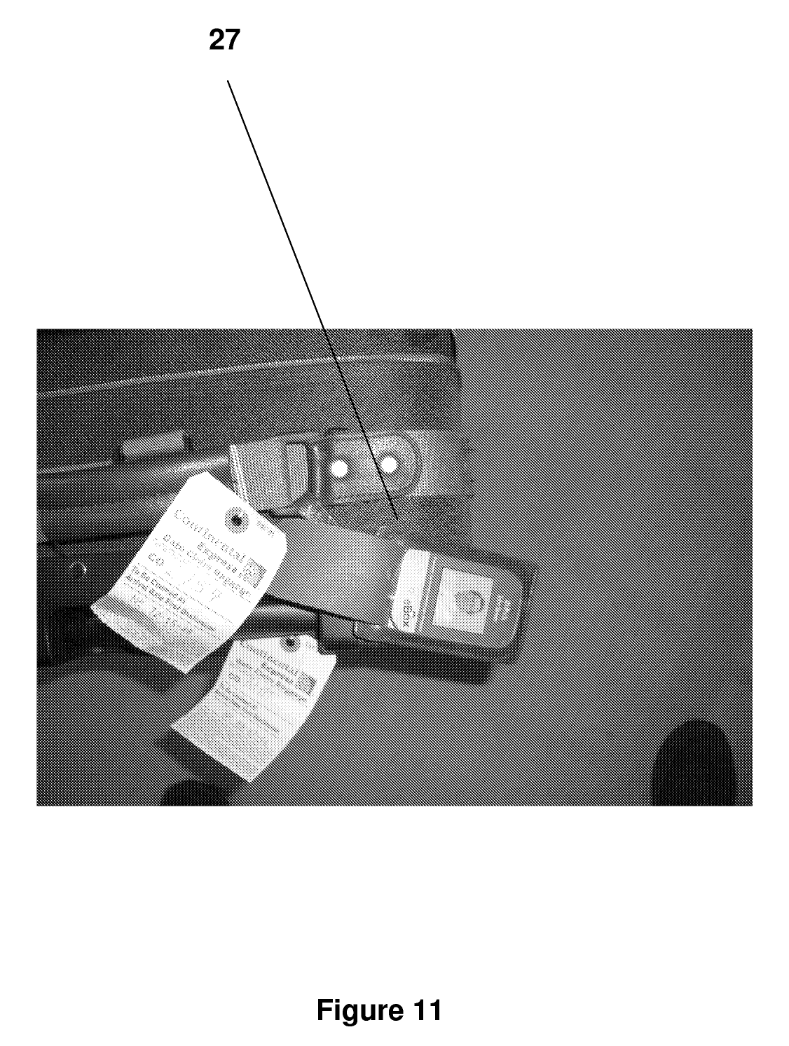

FIG. 11 shows a tag 27 attached to luggage to provide real-time visibility for lost baggage.

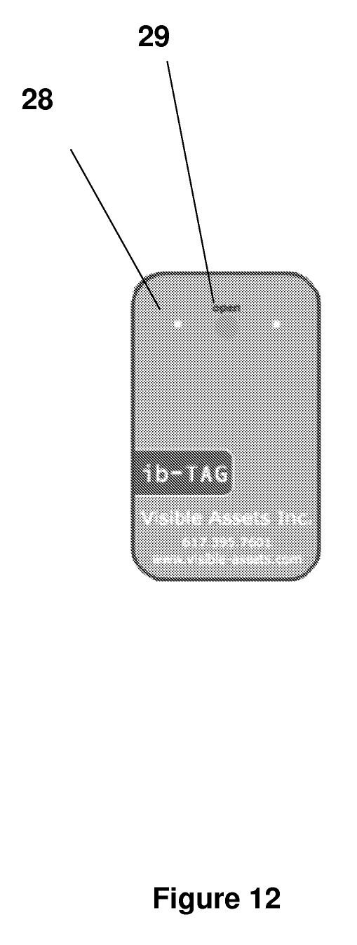

FIG. 12 is a similar tag to that seen in FIG. 11 with a printed overlay.

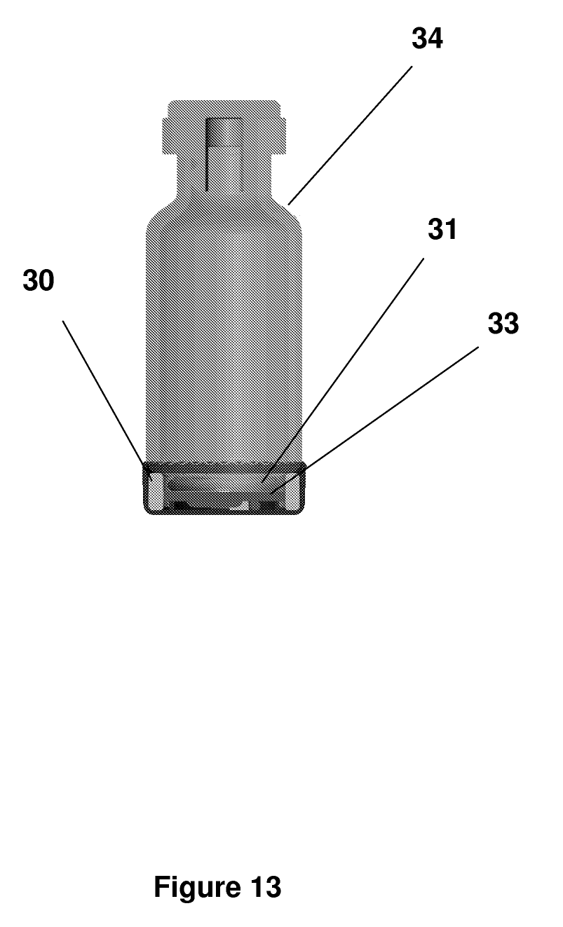

FIG. 13 shows a tag attached to a 2-ml vial 34, that includes a Li battery CR1212, an antenna 30 consisting of a wound coil, a PC board with chip and crystal 33, encapsulated into a 3-mm thick by 16-mm round dot attached to the bottom of the vial 34.

The combination of the RIM encapsulation methods similar to those described in U.S. Pat. No. 6,256,873 , and the low frequency active transceiver tags, as we have described in WO 2006-085291 that include a chip, a battery, a crystal or other frequency reference means, an antenna, with a loop base station reader, has the potential to create:
1. Low-cost, sealed and secure, moisture-proof, credit card size RF tags with battery life of 5-7 years, using thin (0.5 mm) inexpensive Li batteries and with ability read the card in a wallet, or anywhere within an area. These tags may include optional LEDs, LCDs and buttons similar to those described in publication number US 2004-0205350.
2. Low-cost, sealed and secure, moisture-proof, cards 2 mm-3 mm thick that can be used in supply chains, as ID cards, tool visibility systems, surgical instrument visibility systems, and can be read anywhere within a large area (100×100 feet), with a 10-15 year battery life using thicker batteries (1.2 mm to 2.5 mm). These tags may include optional LEDs LCDs and buttons similar to those described in US 2004-0205350. These tags may be used for tracking and providing visibility of airline bags as described in WO 2006-035401.
3. Low-cost, one time use, sealed and secure, moisture proof, devices such as wrist bands 2 mm thick and 1 inch in diameter that can be used to identify patients in hospitals, prisoners, as ID wrist bands, tool visibility systems, and can be read anywhere within a large area (100×100 feet), with a 10-15 year battery life.
4. Low-cost, sealed and secure, moisture-proof, human-implantable sensor devices that can monitor key biological parameters such as glucose levels, EKG metrics, temperature and other metrics often required from implantable medical devices (US 2005-0012617) that can be electronically sensed, in a tag 3 mm thick and 1 inch in diameter that can be surgically implanted into a human., and can be read anywhere within a large area (100×100 feet), with a 10-15 year battery life.
5. Low-cost, sealed and secure, moisture-proof, human-implantable devices that can be used for positive identification of an individual, in a tag 3 mm thick and ½ inch in diameter that can be surgically implanted into a human, and can be read anywhere within a large area (100 ×100 feet), with a 10-15 year battery life. These implantable active ID tags can use secure data protocols that take advantage of the date-time stamp and be virtually uncrackable as compared to the fixed-ID transponder approach adopted by U.S. Pat. No. 5,963,132.
6. Low-cost, sealed and secure, moisture proof, tags that can be mounted on pharmaceutical vials, with optional temperature sensors, and ability to provide identity verification of product to prove it is not counterfeit. The tag can have a form factor of 3 mm by 15 mm and can fit on bottom of vial will have a two-year life with range of five feet to eight feet from a loop antenna. These tags may also be used to provide full visibility and Electronic Article Surveillance for products within a retail setting.
7. Low-cost, sealed and secure, moisture-proof, 2 inch by 3 inch cards 2 mm thick that can be used to identify livestock and provide full livestock pedigree. These livestock tags can be read anywhere within a large area (100×100 feet), with a 10-15 year battery life. These tags may include optional LEDs, LCDs and buttons similar to those described in US 2004-0205350.
8. Tags with various shaped form factors to similar to that described in “1” that can be attached to metal parts for visibility of automotive parts, aircraft parts, surgical instruments and other steel or metal-based tools.
9. A low-cost integrated active transponder tag similar to “1-8” with a battery, crystal, chip and antenna encapsulated using low pressure low temperature methods that can be fabricated without the use of a PC board, similar to that described in U.S. Pat. No. 5,089,877.
10. A smart low-cost tag similar to that described in “9” that has materials added to the encapsulating material that can make the plastic “radiation hardened” so as to make gamma sterilization of a radio tag possible similar to that described by U.S. Pat. No. 4,180,474. These tags would be as small as possible given the range and battery life requirements (e.g. 3-5 mm thick by 12-20 mm in diameter) to minimize the blockage of radiation, so the products (e.g. orthopedic implants, stents, drug eluting stents) would be fully sterilized despite the tag. These tags may also have a radiation detection means so the tag itself could be used as proof of sterilization.
11. A tag similar to “1” except in a package size that might fit onto a shelf face and can be used as an electronic shelf labels (ESL) attached to shelves to display inventory and price in a retail environment similar to that described in US 4,937,586 and US 4,879,756.

As will be recalled, most RFID tags are made from a very thin flexible circuit that fits under a label. This approach is not, however, completely successful in harsh environments. Boxes bearing tags are shipped and handled in hospitals, warehouses, and places that do not always pay attention to a “Handle With Care” sign. In standard packages, many tags get broken because the chip is fragile and is exposed to physical abuse. In accordance with the present invention, however, a manufacturing method yields tags that are waterproof and which are nearly impossible to break or bash. The method of the present invention was originally developed by the assignee to withstand 100,000's of pounds in pressurized containers used for plutonium storage, but the method is now employed more generally.

In one embodiment of the invention, what is described is a radio tag, the radio tag comprising a wire-wound loop antenna having an area optionally exceeding three square inches, a semiconductor chip electrically coupled with the loop antenna, an optional battery electrically coupled with the chip, and an optional crystal electrically coupled with the chip, and an optional liquid-crystal display electrically coupled with the chip, the antenna and chip tuned to a frequency below 1 megahertz, the tag further comprising a low-viscosity liquid surrounding the antenna, the chip, the battery, and the crystal, all at a low temperature. The liquid will have been injection molded under low pressure. After the passage of time at a low temperature the liquid hardens, yielding a sturdy tag. In this context “low temperature” can mean below 100 C., and preferably below 200 F., and more preferably below 100 F. The battery and LCD will have been undamaged by the injection molding process. The result may be a radio tag, the radio tag comprising a wire-wound loop antenna having an area exceeding three square inches, a semiconductor chip electrically coupled with the loop antenna, a battery electrically coupled with the chip, and a crystal electrically coupled with the chip, the antenna and chip tuned to a frequency below 1 megahertz, the tag further comprising a solid plastic surrounding the antenna, the chip, the battery, and the crystal, the solid plastic resulting from solidification of a low-viscosity liquid. A radio tag constructed by this process may be repeatedly struck with sufficient force to drive a nail into wood, and will nonetheless communicate successfully thereafter.

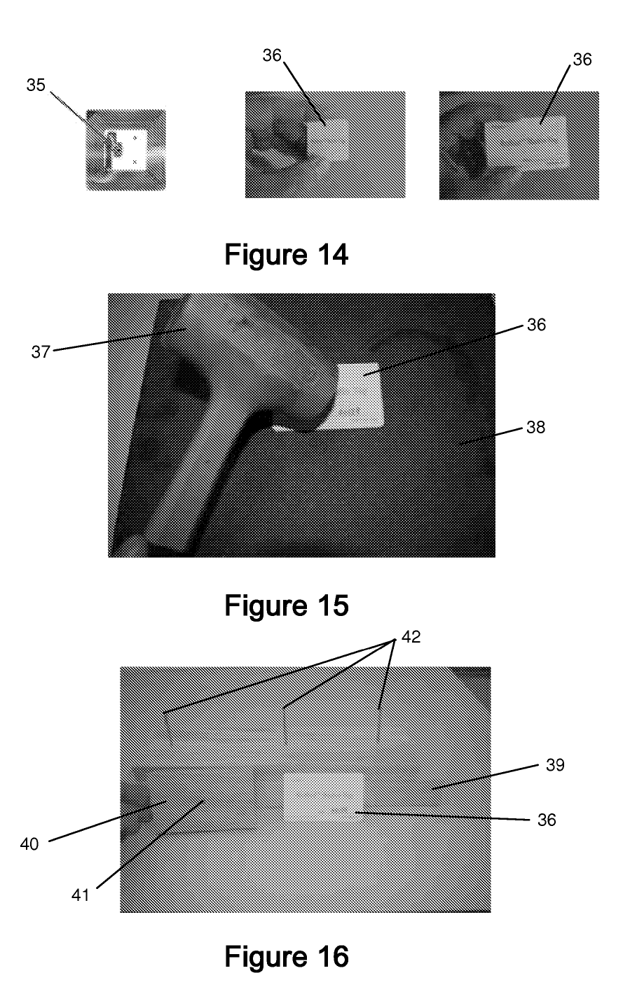

FIG. 14 shows a standard RFID chip (standard WID package on left) 35 and a sturdy tag 36 according to the invention (on the right).

The assignee found that both High frequency (HF) and ultra high frequency (UHF) passive RF-ID tags have had a “fragility” problem in harsh environments. RF-ID tags are fabricated on flexicircuit boards with the integrated circuit attached directly to the board using flip-chip or similar methods. That means a physical blow can break or detach the IC and the tag simply stops working. As will now be described, one of the assignee's standard demonstrations places a sturdy radio tag according to the invention on a two-inch granite block. The assignee then read the tag while slamming it as hard as possible with a sledge hammer. Eventually, over the course of hundreds of blows, the assignee can damage a tag, but it is difficult to damage it.

### EXAMPLE #1.

FIG. 15 shows a sturdy tag 36 according to the invention, placed on a two-inch granite slab 38, ready to be struck with a sledge hammer 37. The assignee was recently challenged by a well known RF-ID consultant regarding the tag packaging according to the invention. The consultant wondered whether the demonstration shown in FIG. 15 was contrived. The consultant wondered whether the assignee did not hit the tag very hard. Thus, the consultant bet the assignee that the assignee could not drive a nail into a piece of wood by hitting the tag 36 with a hammer. The terms of the bet were finalized—US $20.00 per nail, but limited to a total of three nails.

FIG. 16 shows a sturdy tag 36 according to the invention, nearby to a block of wood 40 with a small hole 41 in it, to be used for driving three nails 42. The bet called for the use of the tag 36 and a hammer to pound three nails 42 into a wood block 39. A hard wood block 40 with a small hole 41 was placed over each nail 42 in turn and the tag 36 was placed on top of the block 40. The question was whether the tag 36 would continue to function after the three nails 42 were driven into the wood 39.

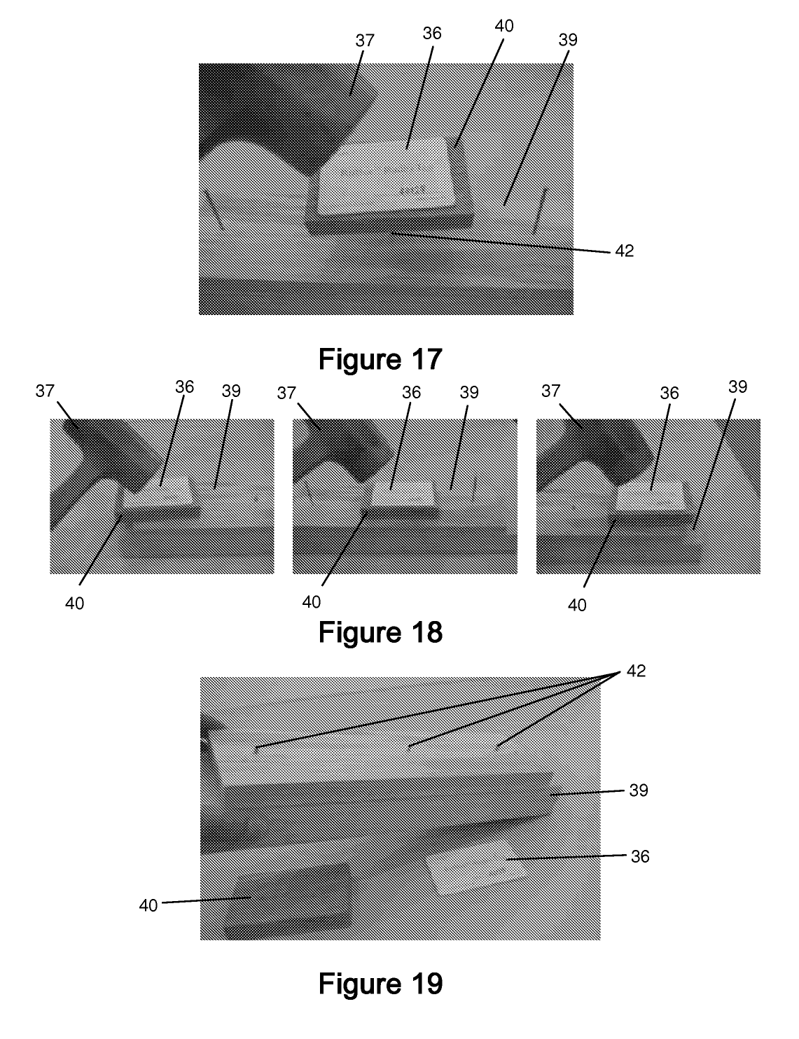

FIG. 17 shows the block of wood 40 of FIG. 16, positioned over a nail 42, with the sturdy tag 36 upon the block of wood 40, ready to be struck by a hammer 37. FIG. 18 shows all three nails 42 of FIG. 16, being driven one by one. FIG. 19 shows the three nails 42 of FIG. 18, driven fully in. The tag 36 still works just like new.

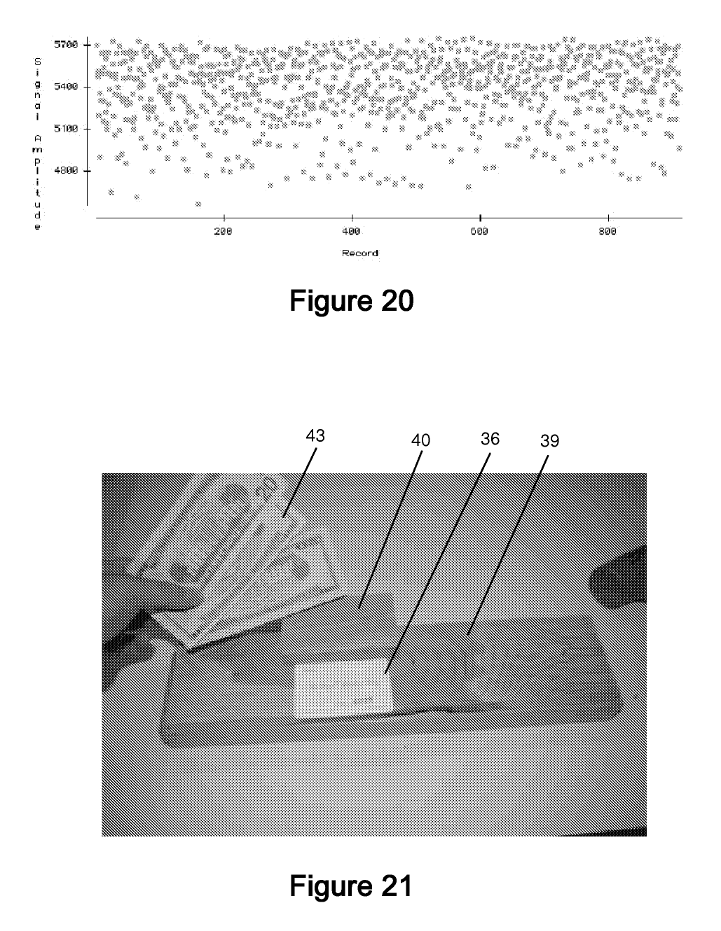

During the hammering activity of FIG. 18, the tag 36 was repeatedly read by a tag reader. Each read included a CRC (cyclic redundancy check) verification that the read had been successful and error-free. FIG. 20 shows the read results plotted over time (horizontal axis) with the vertical axis showing signal strength. Green dots in FIG. 18 represent reads that have a correct CRC. If there were any “bad reads”, meaning reads failing the CRC check, the plotted dots for those reads would have been red in color. As it turns out, there was not a single red dot in the data log. After the hammering had ceased, the tag 36 continued to function.

FIG. 21 shows the bet 43 being paid by the RFID consultant (omitted for clarity in FIG. 21) because the tag reads were successful even after the hammering activity of FIG. 18.

### EXAMPLE #2.

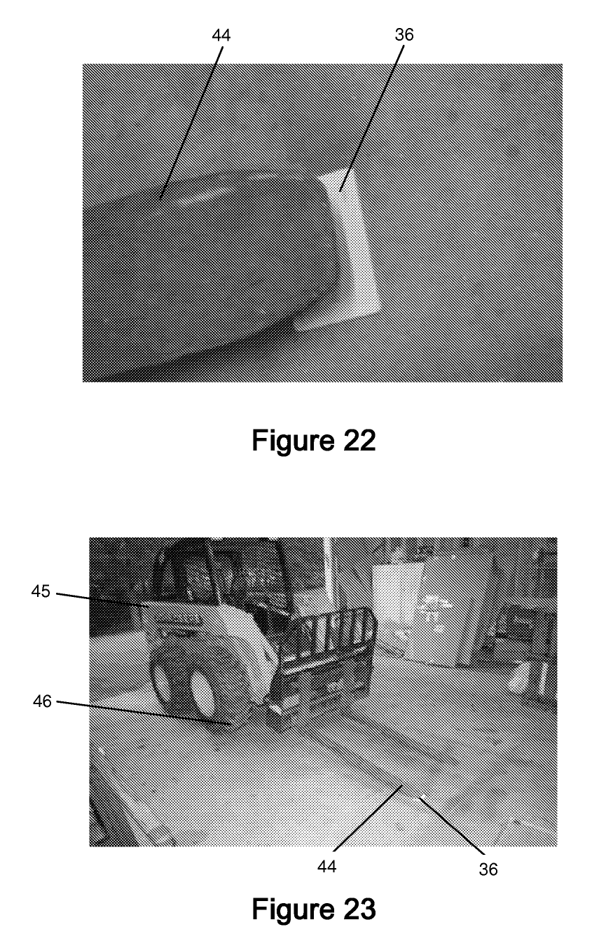

FIG. 22 shows a tongue 47 of a forklift (omitted for clarity in FIG. 22) positioned over a sturdy tag 36 according to the invention, in preparation for a test of the tag 36. The consultant proposed a new test, colloquially called the “Fork Lift Bash” or FLB. The tag 36 was placed under the tongue (fork) of a one-ton forklift. The end of the tongue is used to bash the tag 36 repeatedly. FIG. 23 shows the forklift 45 pushing down upon the tag 36 with enough force to lift both front wheels 46 of the forklift 45. This was repeated several times while the received signal from the tag 36 was monitored.

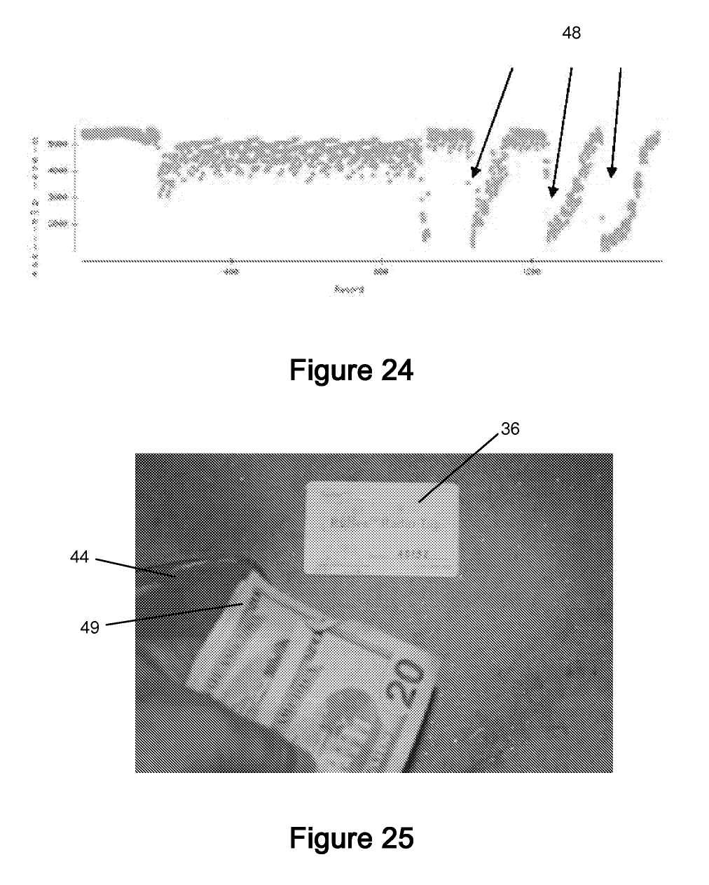

FIG. 24 plots tag reads with correct CRCs during the pressing or “bashing” activity of FIG. 23. The reads are plotted over time (horizontal axis) with the vertical axis showing received signal strength. The drops 48 in signal strength were due to detuning of the antenna because of the close contact to the steel in the tongue. Green dots in FIG. 24 represent reads that have a correct CRC. If there were any “bad reads”, meaning reads failing the CRC check, the plotted dots for those reads would have been red in color. There was not a single red dot in the data log. The assignee was were eventually able to destroy the tag 36 by dragging it across the floor of the warehouse with the full weight of the forklift 45 on the top. FIG. 25 shows a bet being paid 49 because the tag reads were successful even after the pressing activity of FIG. 23.

While the disclosure here describes particular embodiments of the invention, those skilled in the art will have no difficulty whatsoever in devising myriad obvious improvements and variants of the invention, all of which are intended to be embraced within the claims which follow.

1. A radio tag, the radio tag comprising a wire-wound loop antenna having an area exceeding three square inches, a semiconductor chip electrically coupled with the loop antenna, a battery electrically coupled with the chip, and a crystal electrically coupled with the chip, the antenna and chip tuned to a frequency below 1 megahertz, the tag further comprising a low-viscosity liquid surrounding the antenna, the chip, the battery, and the crystal, the radio tag being at low temperature.

2. The radio tag of claim 1 further comprising a liquid crystal display electrically coupled with the chip.

3. A method comprising the steps of:
assembling a wire-wound loop antenna, a semiconductor chip electrically coupled thereto, the antenna and chip tuned to a frequency below 1 megahertz;
injection molding a low viscosity plastic liquid at low temperature, the plastic liquid surrounding the antenna and the chip.

4. A method comprising the steps of:
assembling a wire-wound loop antenna, a semiconductor chip electrically coupled thereto, and a battery electrically coupled thereto, the antenna and chip tuned to a frequency below 1 megahertz;
injection molding a low viscosity plastic liquid at low temperature, the plastic liquid surrounding the antenna and the chip, whereby after solidification of the plastic, the battery is undamaged.

5. A method for use with a radio tag, the radio tag responsive to low-frequency communication, the method comprising the steps of:
repeatedly striking the tag with sufficient force to drive a nail into wood;
thereafter, communicating successfully with the tag by means of low-frequency communication.

6. A radio tag, the radio tag comprising a wire-wound loop antenna having an area exceeding three square inches, a semiconductor chip electrically coupled with the loop antenna, a battery electrically coupled with the chip, and a crystal electrically coupled with the chip, the antenna and chip tuned to a frequency below 1 megahertz, the tag further comprising a solid plastic surrounding the antenna, the chip, the battery, and the crystal, the solid plastic resulting from solidification of a low-viscosity liquid at low temperature.
